(19) United States
(12) Patent Application Publication
(10) Pub. No.: US 2020/0176490 A1
(43) Pub. Date: Jun. 4, 2020

(54) PHOTOELECTRIC CONVERSION DEVICE, PHOTOELECTRIC CONVERSION SYSTEM, AND MOBILE APPARATUS

(71) Applicant: CANON KABUSHIKI KAISHA, Tokyo (JP)

(72) Inventors: Hajime Ikeda, Yokohama-shi (JP); Yusuke Onuki, Fujisawa-shi (JP)

(21) Appl. No.: 16/690,008

(22) Filed: Nov. 20, 2019

(30) Foreign Application Priority Data
Nov. 29, 2018 (JP) 2018-224279

(51) Int. Cl. H01L 27/146

(52) U.S. Cl. CPC H01L 27/1461; H01L 27/14627; H01L 27/1462; H01L 27/14629

(57) ABSTRACT

A photoelectric conversion device includes a first semiconductor region, a second semiconductor region, and a third semiconductor region. The first semiconductor region is of a first conductivity type provided at a position at which a depth from a first face is a first depth. The second semiconductor region is of the second conductivity type provided at a second depth deeper than the first depth, contacting with the first semiconductor region, and applied with a first electric potential from a second face side. The third semiconductor region is of the second conductivity type extending from the first depth to a third depth shallower than the second depth, contacting with the first and second semiconductor regions. The third semiconductor region has a higher impurity concentration than the second semiconductor region, and is applied with a second electric potential lower than the first electric potential.

### BACKGROUND

### Field

One disclosed aspect of the embodiments relates to a photoelectric conversion device, a photoelectric conversion system including the photoelectric conversion device, and a mobile apparatus including the photoelectric conversion device.

### Description of the Related Art

A photoelectric conversion device that performs photoelectric conversion on a light having a long wavelength, such as visible light corresponding to a red wavelength, near-infrared light, infrared light, or the like has been studied. A photoelectric conversion device in which a region provided with a photoelectric conversion unit is formed in a deep region of a semiconductor substrate and thereby the photoelectric conversion efficiency for a light having a long wavelength is improved is known.

Japanese Patent Application Laid-open No. 2010-56345 discloses a photoelectric conversion device that can reduce crosstalk between pixels for visible light and improve sensitivity for infrared light by forming a deeply extending depletion layer of each pixel.

In the configuration of Japanese Patent Application Laid-open No. 2010-56345, signal charges generated in a deep region of the semiconductor substrate by a light having a long wavelength may not move to a region used for collecting signal charges, and thus sensitivity to light is reduced.

### SUMMARY

One disclosed aspect of the embodiments provides a photoelectric conversion device with improved sensitivity to light.

An embodiment has been made in view of problems described above, and one aspect thereof is a photoelectric conversion device including a semiconductor substrate having a first face and a second face. The semiconductor substrate includes at least one first semiconductor region, a second semiconductor region, and a third semiconductor region. The first semiconductor region is of the first conductivity type provided at a position at which a depth from the first face is a first depth. The second semiconductor region is of the second conductivity type provided at a second depth deeper than the first depth from the first face, being in contact with the first semiconductor region, and applied with a first electric potential from the second face side. The third semiconductor region is of the second conductivity type extending from the first depth to a third depth shallower than the second depth, and being in contact with the first semiconductor region and the second semiconductor region. The third semiconductor region has a higher impurity concentration than the second semiconductor region, and is applied with a second electric potential. The second electric potential is an electric potential lower than the first electric potential for an electric charge serving as a carrier of a semiconductor region of the first conductivity type.

Further features of the disclosure will become apparent from the following description of exemplary embodiments with reference to the attached drawings.

### BRIEF DESCRIPTION OF THE DRAWINGS

FIG. 1 is a diagram illustrating a configuration of a photoelectric conversion device.

FIG. 2 is a diagram illustrating a configuration of a pixel.

FIG. 3 is a top view of the pixel.

FIG. 4A and FIG. 4B are sectional views of the pixels.

FIG. 5A, FIG. 5B, and FIG. 5C are sectional views of the pixels.

FIG. 6 is a top view of the pixel.

FIG. 7A and FIG. 7B are sectional views of the pixels.

FIG. 8 is a sectional view of the pixels.

FIG. 9 is a sectional view of the pixels.

FIG. 10A is a top view of the pixel, and FIG. 10B is a sectional view of the pixels.

FIG. 11A is a top view of the pixel, and FIG. 11B is a sectional view of the pixels.

FIG. 12A is a top view of the pixel, and FIG. 12B is a sectional view of the pixels.

FIG. 13A is a top view of the pixel, and FIG. 13B, FIG. 13C, and FIG. 13D are sectional views of the pixels.

FIG. 14A is a top view of the pixel, and FIG. 14B is a sectional view of the pixel.

FIG. 15 is a top view of the pixels.

FIG. 16 is a sectional view of the pixels.

FIG. 17 is a sectional view of the pixels.

FIG. 18 is a sectional view of the pixels.

FIG. 19 is a diagram illustrating a configuration of a photoelectric conversion system.

FIG. 20A and FIG. 20B are diagrams illustrating a mobile apparatus.

### DESCRIPTION OF THE EMBODIMENTS

Preferred embodiments of the disclosure will now be described in detail in accordance with the accompanying drawings. Note that the conductivity type of each transistor described in the embodiments below is merely an example and is not limited only to the conductivity type described in the embodiments. With respect to the conductivity type described in the embodiments, the conductivity type may be appropriately changed, and the electric potentials of the gate, the source, and the drain of transistors are appropriately changed in accordance with the change. For example, in a case of a transistor operated as a switch, the low level and the high level of the electric potential supplied to the gate may be opposite with respect to those described in the embodiments in accordance with the change of the conductivity type. Further, the conductivity type of each semiconductor region described in the embodiments below is also merely an example and is not limited only to the conductivity type described in the embodiments. With respect to the conductivity type described in the embodiments, the conductivity type may be appropriately changed, and the electric potentials of the semiconductor regions are appropriately changed in accordance with the change.

### First Embodiment

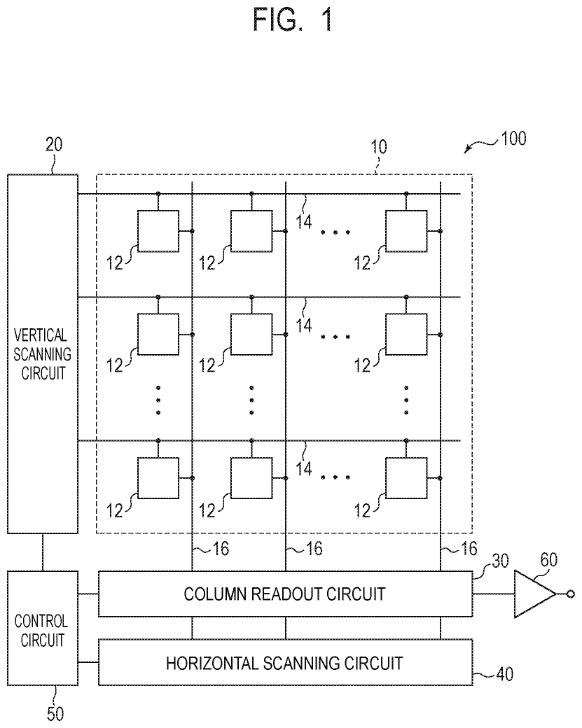

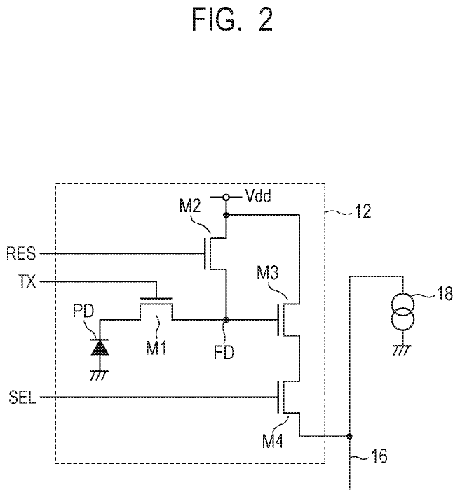

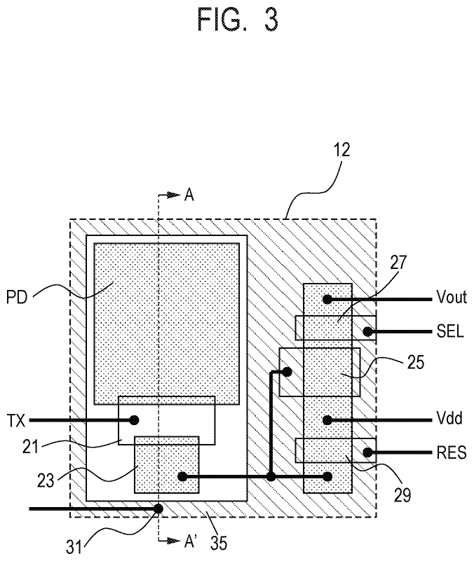

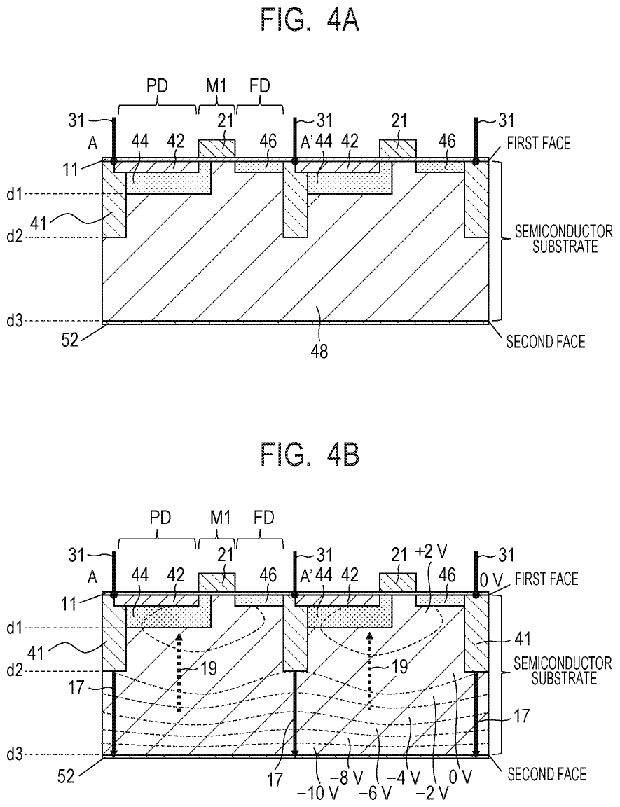

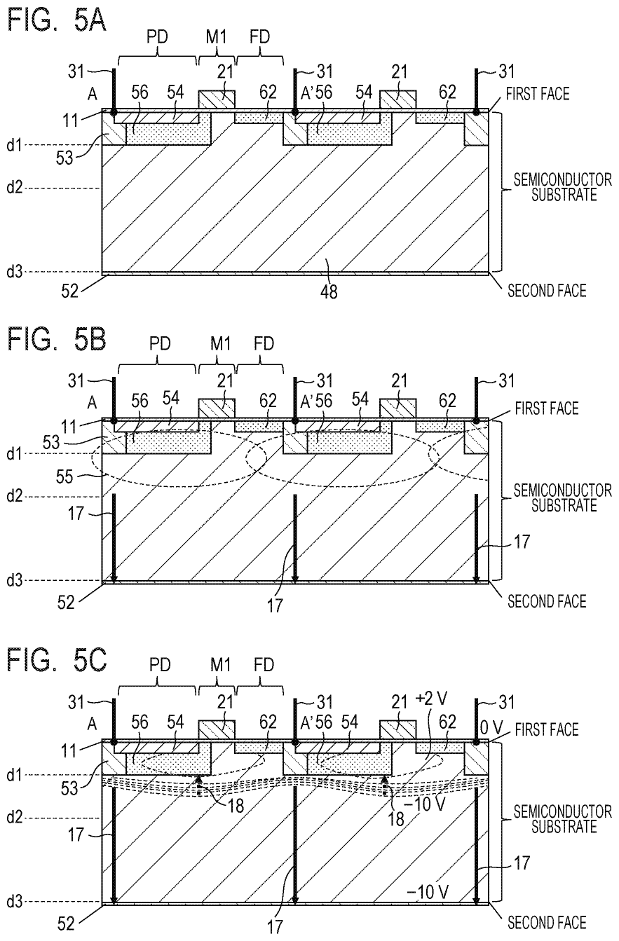

FIG. 1 is a block diagram illustrating the general configuration of a solid state imaging device according to the present embodiment that is an example of a photoelectric conversion device. FIG. 2 is an equivalent circuit diagram of a pixel of the solid state imaging device according to the present embodiment. FIG. 3 is a diagram illustrating a plan layout of the pixel of the solid state imaging device according to the present embodiment. FIG. 4A and FIG. 4B are schematic sectional views of the pixels of the solid state imaging device according to the present embodiment. FIG. 5A, FIG. 5B, and FIG. 5C are plan views of the pixels of the solid state imaging device according to a comparative example of the present embodiment.

As illustrated in FIG. 1, a solid state imaging device 100 according to the present embodiment has a pixel region 10, a vertical scanning circuit 20, a column readout circuit 30, a horizontal scanning circuit 40, a control circuit 50, and an output circuit 60.

In the pixel region 10, a plurality of pixels 12 arranged in a matrix over a plurality of rows and a plurality of columns are provided. On each row of the pixel arrays in the pixel region 10, a control signal line 14 is arranged extending in the row direction (the horizontal direction in FIG. 1). The control signal line 14 is connected to the pixels 12 aligned in the row direction, respectively, to form a signal line common to these pixels 12. Further, on each column of the pixel arrays in the pixel region 10, a vertical output line 16 is arranged extending in the column direction (the vertical direction in FIG. 1). The vertical output line 16 is connected to the pixels 12 aligned in the column direction, respectively, to form a signal line common to these pixels 12.

The control signal line 14 on each row is connected to the vertical scanning circuit 20. The vertical scanning circuit 20 is a circuit unit that supplies, to the pixels 12 via the control signal lines 14, control signals used for driving readout circuits inside the pixels 12 when pixel signals are read out from the pixels 12. One end of the vertical output lines 16 on each column is connected to the column readout circuit 30. A pixel signal read out from each pixel 12 is input to the column readout circuit 30 via the vertical output line 16. The column readout circuit 30 is a circuit unit that performs a predetermined signal process, for example, a signal process such as an amplification process, an analog-to-digital (AD) conversion process, or the like on a pixel signal read out from the pixel 12. The column readout circuit 30 may include a differential amplifier circuit, a sample and hold circuit, an AD converter circuit, or the like.

The horizontal scanning circuit 40 is a circuit unit that supplies, to the column readout circuit 30, control signals for sequentially transferring pixel signals processed in the column readout circuit 30 to the output circuit 60 on a column basis. The control circuit 50 is a circuit unit used for supplying a control signal that controls operations and their timing of the vertical scanning circuit 20, the column readout circuit 30, and the horizontal scanning circuit 40. The output circuit 60 is a circuit unit formed of a buffer amplifier, a differential amplifier, or the like and is used for outputting a pixel signal read out from the column readout circuit 30 to a signal processing unit outside the solid state imaging device 100.

As illustrated in FIG. 2, each of the pixels 12 has a photoelectric conversion unit PD, a transfer transistor M1, a reset transistor M2, an amplification transistor M3, and a select transistor M4. The photoelectric conversion unit PD is a photodiode, the anode thereof is connected to the ground voltage line, and the cathode thereof is connected to the source of the transfer transistor M1, for example. The drain of the transfer transistor M1 is connected to the source of the reset transistor M2 and the gate of the amplification transistor M3. A connection node of the drain of the transfer transistor M1, the source of the reset transistor M2, and the gate of the amplification transistor M3 is a so-called floating diffusion (FD) and forms a charge-to-voltage conversion unit formed of a capacitor component included in the node. The drain of the reset transistor M2 and the drain of the amplification transistor M3 are connected to a power source voltage line (Vdd). The source of the amplification transistor M3 is connected to the drain of the select transistor M4. The source of the select transistor M4 is connected to the vertical output line 16. The other end of the vertical output line 16 is connected to a current source 18.

In the case of the circuit configuration illustrated in FIG. 2, the control signal line 14 includes a transfer gate signal line TX, a reset signal line RES, and a select signal line SEL. The transfer gate signal line TX is connected to the gate of the transfer transistor M1. The reset signal line RES is connected to the gate of the reset transistor M2. The select signal line SEL is connected to the gate of the select transistor M4.

The photoelectric conversion unit PD converts (photoelectrically converts) an incident light into an amount of charges corresponding to a light amount of the incident light and accumulates the generated charges. When turned on, the transfer transistor M1 transfers charges in the photoelectric conversion unit PD to the floating diffusion FD. The floating diffusion FD has a voltage corresponding to the amount of the charges transferred from the photoelectric conversion unit PD by charge-to-voltage conversion caused by the capacitance of the floating diffusion PD. The amplification transistor M3 is configured such that the power source voltage Vdd is supplied to the drain and a bias current is supplied to the source from the current source 18 via the select transistor M4 and forms an amplifier unit whose gate is the input node (source follower circuit). Thereby, the amplification transistor M3 outputs a signal based on the voltage of the floating diffusion FD to the vertical output line 16 via the select transistor M4. When turned on, the reset transistor M2 resets the floating diffusion FD to a voltage corresponding to the power source voltage Vdd.

FIG. 3 is a schematic diagram illustrating a plan layout when the pixel 12 of the present embodiment is viewed from the top face (on the incidence face side). In FIG. 3, the same elements as those illustrated in FIG. 1 and FIG. 2 are labelled with the same reference as those in FIG. 1 and FIG. 2. Each front electrode 31 is an electrode that applies an electric potential to a P-type isolation region 35. The P-type isolation region 35 is arranged in the outer circumference of the photoelectric conversion unit PD.

Further, a transfer gate 21 is provided as a part of the transfer transistor M1 that transfers charges of the photoelectric conversion unit PD. The transfer gate 21 is provided between a floating diffusion region 23, which is a portion of the floating diffusion (FD), and the photoelectric conversion unit PD. Further, the transfer gate signal line TX is connected to the transfer gate 21.

The floating diffusion region 23 is connected to an amplification gate 25, which is the gate of the amplification transistor M3, via an FD connecting wiring. Further, a select gate 27 that is the gate of the select transistor M4 is connected to the select signal line SEL. One of the source and the drain of the select transistor M4 is connected to a signal line Vout that is the vertical output line 16. The other of the source and the drain of the select transistor M4 is also the source of the amplification transistor M3. The power source voltage Vdd is supplied to the drain of the amplification transistor M3.

Further, a reset gate 29 that is the gate of the reset transistor M2 is connected to the reset signal line RES. The drain of the reset transistor M2 is also the drain of the amplification transistor M3. The source of the reset transistor M2 is connected to the floating diffusion region 23 and the amplification gate 25 via the FD connecting wiring.

FIG. 4A is a diagram illustrating the cross section of two pixels taken along the line A-A′ illustrated in FIG. 3. In FIG. 4A, the same elements as those illustrated in FIG. 1 to FIG. 3 are labelled with the same reference as those in FIG. 1 to FIG. 3. A gate insulating film 11 is provided on a first face of a semiconductor substrate. The gate insulating film 11 is typically formed of a silicon oxide film.

The photoelectric conversion unit PD has a P-type semiconductor region 42 and an N-type semiconductor region 44. The N-type semiconductor region 44 is a charge accumulation region that accumulates charges (electrons in the present embodiment) generated by photoelectric conversion. Further, a P-type semiconductor region 48 is provided under the N-type semiconductor region 44.

The P-type semiconductor region 42 is formed so as to be in contact with the first face. The P-type semiconductor region 42 suppresses charges generated by a dark current generated on the surface of the semiconductor substrate from flowing into the N-type semiconductor region 44.

The N-type semiconductor region 46 is the floating diffusion region 23 illustrated in FIG. 3.

In FIG. 3, the P-type isolation region 35 arranged on the outer circumference of the photoelectric conversion unit PD is illustrated as a P-type isolation region 41 in FIG. 4A. The P-type isolation region 41 is connected to the front electrode 31.

Further, a back electrode 52 is provided under a second face of the semiconductor substrate. The back electrode 52 is formed so as to be in contact with the P-type semiconductor region 48. Further, the back electrode 52 is provided over a plurality of pixels. Typically, the back electrode 52 is provided over the pixel region 10 illustrated in FIG. 1. Note that the arrangement of the back electrode 52 is not limited to the example described above, and the back electrode 52 may be isolated on a pixel row basis. Further, the back electrode 52 may be isolated on a pixel column basis. Further, the back electrode 52 may be isolated on a block basis, each block having the pixels 12 of a plurality of rows and a plurality of columns.

With respect to the first face of the semiconductor substrate as a reference, the N-type semiconductor region 44 (bottom) is provided at a position of a depth d1. The depth of a semiconductor region is defined as the distance from the first face to the second face of that semiconductor region. A depth is deeper than another depth when its distance is longer than the distance of the other depth. Similarly, a depth is shallower than another depth when its distance is shorter than the distance of the other depth. Further, the P-type semiconductor region 48 (bottom) is provided at a position of a depth d3 that is deeper than the depth d1. The P-type isolation region 41 is provided so as to extend from at least the depth d1 to a depth d2 that is shallower than the depth d3 in the depth direction from the first face.

The front electrode 31 is supplied with an electric potential whose potential relative to electrons that are carriers of the N-type semiconductor region 44 is lower than that of the back electrode 52. In the present embodiment, the electric potential of the front electrode 31 is 0 V, and the electric potential of the back electrode 52 is −10 V.

Further, in the present embodiment, the impurity concentration of the P-type semiconductor region 48 is lower than the impurity concentration of the P-type semiconductor region 42. When there is a relationship that the P-type semiconductor region 48 has a lower impurity concentration than the P-type isolation region 41, a hall current flows through the P-type semiconductor region 48, and thereby an electric potential gradient in the substrate depth direction can be formed in the P-type semiconductor region 48.

Further, the impurity concentration of the P-type semiconductor region 42 is 2×10¹⁹ [atom/cm³]. Note that, in the present specification, an impurity concentration is represented as a concentration of impurities present in a semiconductor region.

FIG. 4B is a schematic diagram illustrating equipotential lines for indicating an electric potential distribution in the configuration illustrated in FIG. 4A.

Since the front electrode 31 is conducted to the back electrode 52 via the P-type isolation region 41 and the P-type semiconductor region 48, a hall current 17 flows. However, the impurity concentration of the P-type semiconductor region 48 is 1×10¹¹ [atom/cm³] as described above. Therefore, since the electric resistance between the front electrode 31 and the back electrode 52 is high, an electric potential gradient occurs in the P-type semiconductor region 48. With such an electric potential gradient, electrons generated in the P-type semiconductor region 48 by photoelectric conversion performed in response to the incidence of light can easily move to the N-type semiconductor region 44. Therefore, since the number of electrons collected in the N-type semiconductor region 44 increases, the sensitivity of the photoelectric conversion device is improved.

Further, a depletion layer is formed of the N-type semiconductor region 44, P-type semiconductor region 48, and the P-type semiconductor region 42.

It is preferable that the P-type isolation region 41 be arranged so as to extend to a position deeper than the N-type semiconductor region 44. It is more preferable that the P-type isolation region 41 extend to a position deeper than the depletion layer formed of the N-type semiconductor region 44, the P-type semiconductor region 48, and the P-type semiconductor region 42.

The reason for the above will be described with reference to FIG. 5A, FIG. 5B, and FIG. 5C.

FIG. 5A illustrates a configuration in which the P-type isolation region 53 extends to the depth d1 that is the same depth as the bottom of the N-type semiconductor region 56. As with FIG. 4A, a voltage of 0 V is applied from the front electrode 31 to the P-type isolation region 53. The N-type semiconductor region 56 is a charge accumulation layer and is provided under the P-type semiconductor region 54. The N-type semiconductor region 62 is the floating diffusion region 23. A voltage of −10 V is applied to the back electrode 52.

FIG. 5B is a schematic diagram illustrating equipotential lines for indicating an electric potential distribution in a configuration illustrated in FIG. 5A. In the configuration of FIG. 5A, since the P-type isolation region 53 extends only to the depth d1 as illustrated in FIG. 5B, depletion layers 55 of adjacent pixels are connected to each other.

FIG. 5C illustrates an electric potential distribution in such a case. For the hall current 17 between the P-type isolation region 53 and the back electrode 52, the depletion layer is a high-resistance region in which a current does not easily flow. Therefore, while the electric potential gradient occurs from the depth d2 to the depth d3 in the P-type semiconductor region 48 in FIG. 4B, the electric potential gradient is concentrated near the depth d1 in FIG. 5C. This results in a small electric potential gradient between the depth d2 and the depth d3. Therefore, drive force to move electrons generated in the P-type semiconductor region 48 to the N-type semiconductor region 56 is reduced. This causes a disadvantage of an increase in so-called crosstalk in which electrons generated in the P-type semiconductor region 48 in a certain pixel are collected in the N-type semiconductor region 56 of another pixel.

On the other hand, in the photoelectric conversion device of the present embodiment, the P-type isolation region 41 extends to a position deeper than the N-type semiconductor region 44 as illustrated in FIG. 4A. Thereby, electrons generated in the P-type semiconductor region 48 can easily move to the N-type semiconductor region 44, as described above. Therefore, since the electrons collected in the N-type semiconductor region 44 increase, the sensitivity of the photoelectric conversion device is improved.

Note that it is preferable that the impurity concentration of the P-type isolation region 41 be at least higher than that of the P-type semiconductor region 48. With the increased impurity concentration of the P-type isolation region 41, the electric resistance for the hall current can be reduced. Further, depletion of the P-type isolation region 41 due to the electric potential difference from the N-type semiconductor region 44 can be suppressed.

Further, it is preferable that the electric potential difference inside the P-type isolation region 41 be smaller than the electric potential difference in the P-type semiconductor region 48. Accordingly, since most of the electric potential difference between the front electrode 31 and the back electrode 52 can be used for forming an electric potential gradient in the P-type semiconductor region 48, crosstalk can be further reduced.

### Second Embodiment

The present embodiment will be described mainly for features different from the first embodiment. In the present embodiment, a P-type semiconductor region PDS having a higher impurity concentration than the P-type semiconductor region 48 is provided under the N-type semiconductor region that is a region for accumulating signal charges in the photoelectric conversion unit PD. Thereby, the capacitance of a depletion layer generated between the N-type semiconductor region 44 and the P-type semiconductor region provided thereunder is increased to be larger than that in the first embodiment. Accordingly, the saturation charge amount of the photoelectric conversion unit PD is increased to be larger than that of the first embodiment.

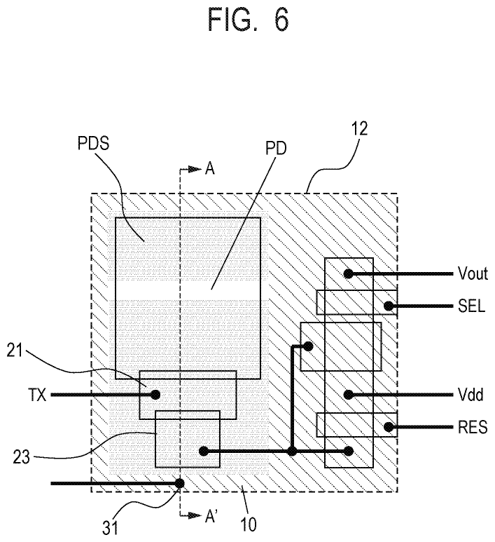

In the present embodiment, as illustrated in FIG. 6, the P-type semiconductor region PDS is provided at a position overlapping with the photoelectric conversion unit PD in a plan view. The P-type semiconductor region PDS has a higher impurity concentration than the P-type semiconductor region 48.

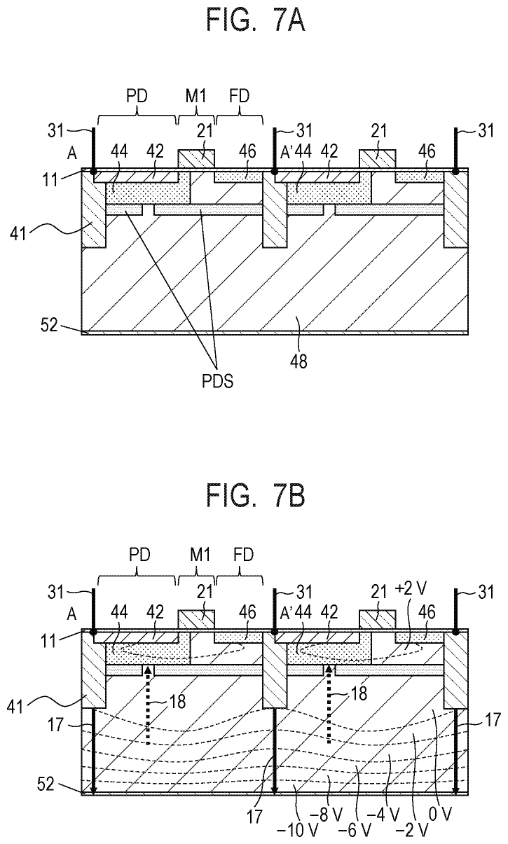

FIG. 7A is a sectional view of a region taken along the line A-A′ illustrated in FIG. 6. The P-type semiconductor region PDS is provided under the N-type semiconductor region 44 so as to be in contact with the bottom of the N-type semiconductor region 44. Therefore, a PN junction is formed of the N-type semiconductor region 44 and the P-type semiconductor region PDS.

In a depletion layer generated between the N-type semiconductor region 44 and the P-type semiconductor region PDS, expansion of the depletion layer is suppressed compared to the depletion layer generated between the N-type semiconductor region 44 and the P-type semiconductor region 48 in the first embodiment. As a result, the capacitance of the depletion layer generated in the present embodiment is increased to be larger than the capacitance of the depletion layer occurring in the first embodiment. Therefore, the saturation charge amount of the photoelectric conversion unit PD is increased compared to the first embodiment.

Further, in the present embodiment, as illustrated in FIG. 6 and FIG. 7A, a slit is provided to the P-type semiconductor region PDS so as to isolate the P-type semiconductor regions PDS from each other. As illustrated in FIG. 7B, signal charges (electrons) generated inside the P-type semiconductor region 48 pass through the slit between the P-type semiconductor regions PDS and move to the N-type semiconductor region 44. By providing a slit in such a way, signal charges (electrons) generated in the P-type semiconductor region 48 can easily move to the N-type semiconductor region 44. It is therefore possible to improve sensitivity to a light having a wavelength (typically, near-infrared light or infrared light) at which signal charges are generated in the P-type semiconductor region 48.

As described above, in the photoelectric conversion device of the present embodiment, a PN junction is formed between the P-type semiconductor region PDS having a higher impurity concentration than the P-type semiconductor region 48 and the N-type semiconductor region 44. It is therefore possible to improve the saturation charge amount of the photoelectric conversion unit PD. Further, by providing a slit between the P-type semiconductor regions PDS, an advantage of improved sensitivity of the photoelectric conversion unit PD is obtained.

### Third Embodiment

A photoelectric conversion device of the present embodiment will be described mainly for features different from the first embodiment.

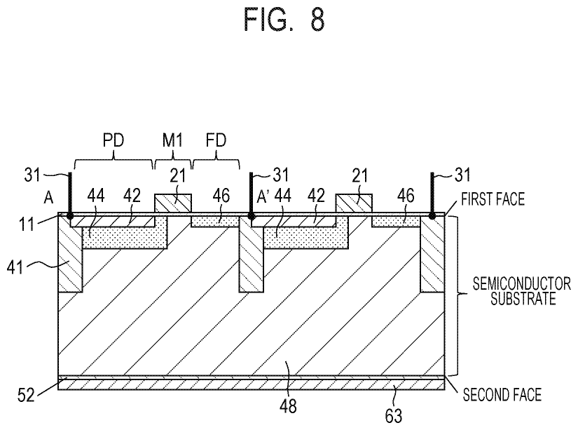

FIG. 8 is a sectional view of the pixel of the photoelectric conversion device of the present embodiment. Note that the layout when viewed from the top face may be the same as that of the first embodiment.

In the present embodiment, a so-called surface irradiation-type photoelectric conversion device in which light enters the semiconductor substrate from the first face side is illustrated.

The photoelectric conversion device of the present embodiment is provided with a reflection member 63 under the second face of the semiconductor substrate. As the reflection member 63, a metal such as aluminum, silver, copper, or the like can be typically used, for example. With the reflection member 63 being provided, a light transmitting through the P-type semiconductor region 48 is reflected to the P-type semiconductor region 48. It is therefore possible to further improve sensitivity of the photoelectric conversion unit PD.

Note that, with respect to the reflection member 63, when the back electrode 52 is made of a metal such as aluminum, copper, or the like, it is also possible to omit the reflection member 63 by using the back electrode 52 as a reflection member.

### Fourth Embodiment

A photoelectric conversion device of the present embodiment will be described mainly for features different from the first embodiment.

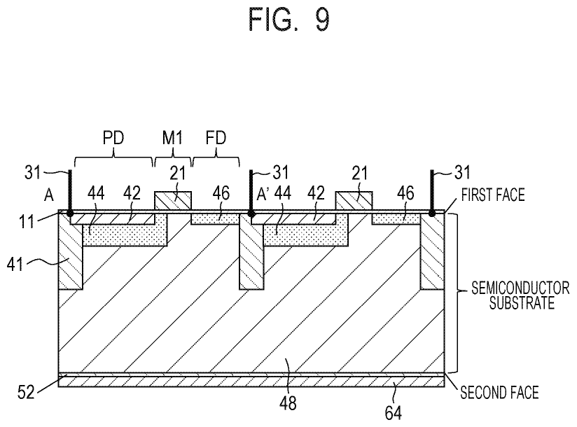

FIG. 9 is a sectional view of the pixel of the photoelectric conversion device of the present embodiment. Note that the layout when viewed from the top face may be the same as that of the first embodiment.

In the present embodiment, a so-called rear face irradiation-type photoelectric conversion device in which light enters the semiconductor substrate from the second face side is illustrated.

In the present embodiment, the back electrode 52 is a transparent electrode. A material of the transparent electrode can be various materials such as indium oxide, tin oxide, titanium oxide, graphene, a mixture thereof, or the like.

An antireflection film 64 is provided under the back electrode 52 (on the light incidence face side). Thereby, the reflection of an incident light by the back electrode 52 can be suppressed. It is therefore possible to improve sensitivity of the photoelectric conversion unit PD.

Note that the antireflection film 64 may be formed of a single layer or may be a film in which a plurality of films having different refractive indexes are stacked.

### Fifth Embodiment

A photoelectric conversion device of the present embodiment will be described mainly for features different from the first embodiment.

The photoelectric conversion device of the present embodiment has a configuration in which a pixel has a single micro-lens and a plurality of photoelectric conversion units PD configured to receive light that has transmitted through the single micro-lens. The photoelectric conversion device having such a configuration can output a signal used for focus detection of a phase difference detection scheme.

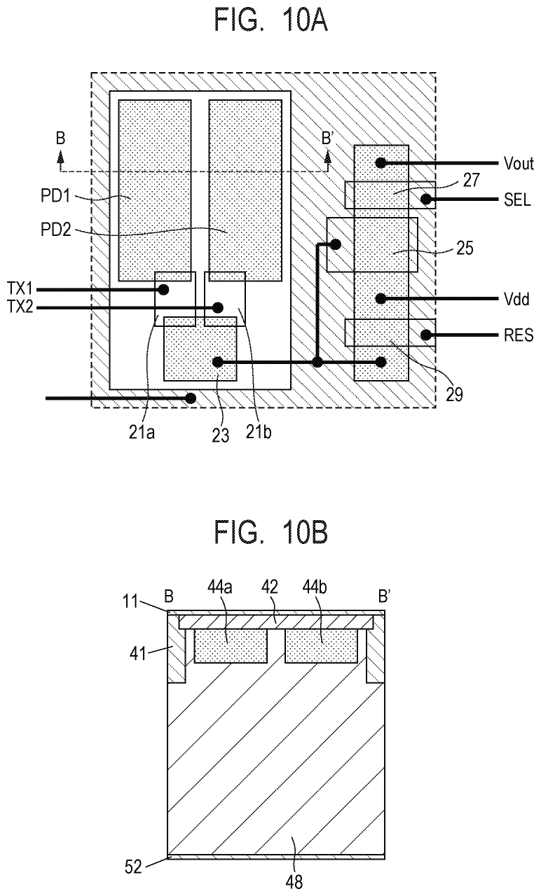

FIG. 10A is a top view of a pixel of the present embodiment. In FIG. 10A, members having the same function as those illustrated in FIG. 3 of the first embodiment are also labeled with the same references as those in FIG. 3.

The pixel of the present embodiment has a plurality of photoelectric conversion units PD1 and PD2. Further, the pixel has a transfer gate 21a provided in association with the photoelectric conversion unit PD1 and a transfer gate 21b provided in association with the photoelectric conversion unit PD2. The transfer gates 21a and 21b share the floating diffusion region 23. A transfer gate signal line TX1 is connected to the transfer gate 21a. A transfer gate signal line TX2 is connected to the transfer gate 21b.

The arrangement of the P-type isolation region 41 will be described. FIG. 10B is a sectional view at a position taken along the line B-B′ illustrated in FIG. 10A. In the configuration of FIG. 10B, the P-type isolation regions 41 are provided at a position where a plurality of pixels are isolated from each other and, in one single pixel, a position where a region in which the photoelectric conversion unit PD is provided is isolated from a region in which a group of transistors are arranged. The region in which the group of transistors are arranged is a region in which an amplification transistor, a reset transistor, and a select transistor are provided. On the other hand, the P-type isolation region 41 is not arranged between the photoelectric conversion unit PD1 and the photoelectric conversion unit PD2.

The configuration of FIG. 10A and FIG. 10B described above can be preferably used in a surface incidence-type photoelectric conversion device described in the third embodiment. Further, the configuration of FIG. 10A and FIG. 10B can be preferably used in the photoelectric conversion device that uses photoelectric conversion of a light such as visible light having a shorter wavelength than near-infrared light. This is because photoelectric conversion of a light having a wavelength in the visible light range is performed near the surfaces of the photoelectric conversion units PD1 and PD2. Therefore, signal charges are accumulated in the N-type semiconductor region 44a or 44b of the photoelectric conversion unit PD1 or PD2 in accordance with an incidence position.

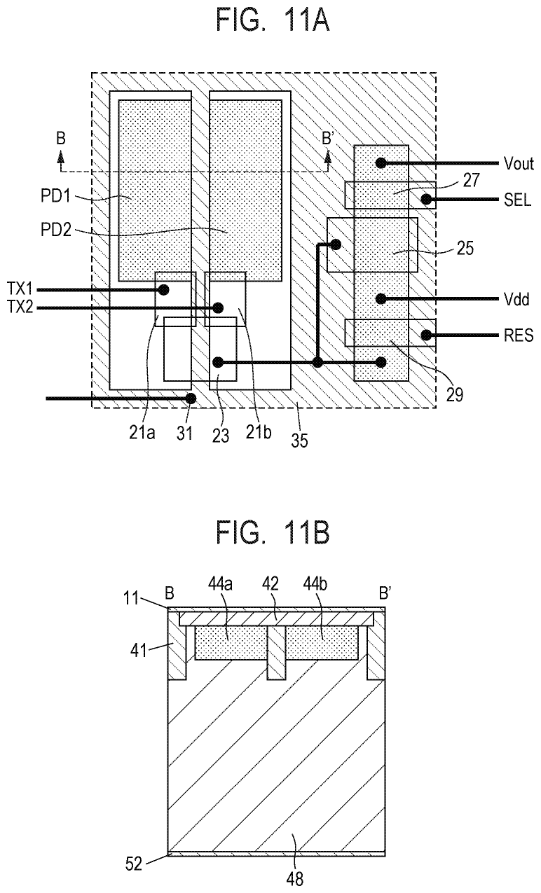

FIG. 11A and FIG. 11B are diagrams illustrating another arrangement of the P-type isolation region 41. In FIG. 11A and FIG. 11B, members having the same function as those illustrated in FIG. 10A and FIG. 10B are also labeled with the same references as those in FIG. 10A and FIG. 10B.

In the form illustrated in FIG. 11A and FIG. 11B, in addition to the P-type isolation region 41 illustrated in FIG. 10A and FIG. 10B, the P-type isolation region 41 is further provided between the photoelectric conversion unit PD1 and the photoelectric conversion unit PD2. FIG. 11B is a sectional view at a position taken along the line B-B′ illustrated in FIG. 11A. The P-type isolation region 41 is provided between the N-type semiconductor region 44a and the N-type semiconductor region 44b. In FIG. 11B, the P-type isolation region 41 is provided so as to extend from the depth of the bottom of the P-type semiconductor region 42 to a depth deeper than the bottoms of the N-type semiconductor regions 44a and 44b.

The form illustrated in FIG. 11A and FIG. 11B can be applied to both the surface incidence-type photoelectric conversion device and the rear face incidence-type photoelectric conversion device. In both the photoelectric conversion devices, crosstalk between charges generated in and near the photoelectric conversion unit PD1 and charges generated in and near the photoelectric conversion unit PD2 can be reduced.

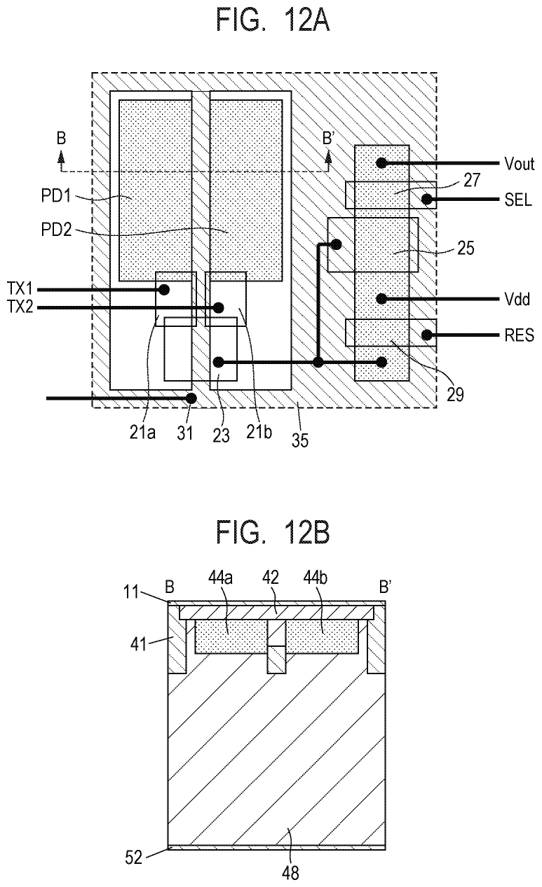

In the form illustrated in FIG. 12A and FIG. 12B, as with FIG. 11A and FIG. 11B, the P-type isolation region 41 is further provided between the photoelectric conversion unit PD1 and the photoelectric conversion unit PD2 in addition to the P-type isolation region 41 illustrated in FIG. 10A and FIG. 10B. FIG. 12B is a sectional view at a position taken along the line B-B′ illustrated in FIG. 12A. In FIG. 11B, the P-type isolation region 41 is provided so as to extend from the depth of the bottom of the P-type semiconductor region 42 to a depth deeper than the bottom of the N-type semiconductor regions 44a and 44b. In FIG. 12B, the P-type isolation region 41 is provided so as to extend from a position deeper than the position of the bottom of the P-type semiconductor region 42 to a depth deeper than the bottoms of the N-type semiconductor regions 44a and 44b.

The form illustrated in FIG. 12A and FIG. 12B can be applied to both the surface incidence-type photoelectric conversion device and the rear face incidence-type photoelectric conversion device. In both the photoelectric conversion devices, when one of the photoelectric conversion units PD1 and PD2 is saturated and signal charges overflow, the signal charges overflow not into a photoelectric conversion unit in another pixel but into the other of the photoelectric conversion units PD1 and PD2 in the same pixel. When a pixel has a color filter, color filters in different colors may be provided to adjacent pixels. In such a case, when signal charges in one of the photoelectric conversion units PD1 and PD2 of a certain pixel overflow into a photoelectric conversion unit PD1 or PD2 in another pixel, this causes so-called color mixing by which an image having a different color ratio from the original color ratio is produced. With the form illustrated in FIG. 12A and FIG. 12B, since signal charges crosstalk between the photoelectric conversion units PD1 and PD2 in the same pixel as described above, the likelihood of occurrence of color mixing can be reduced.

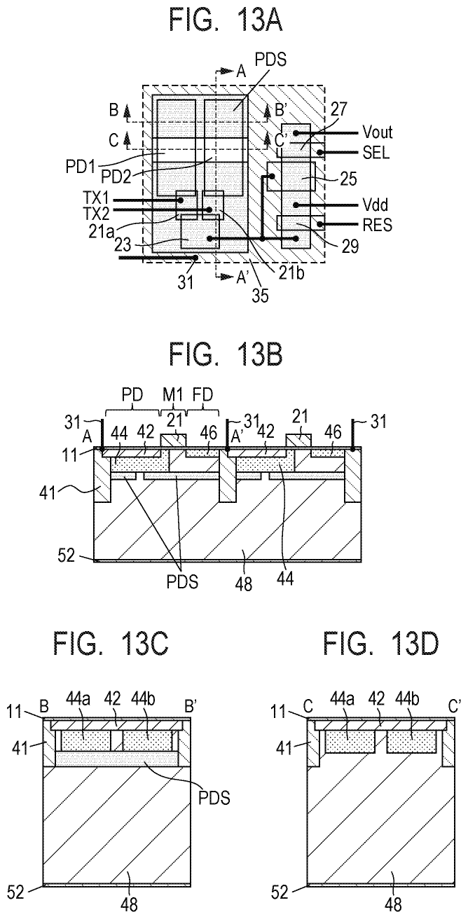

Further, the form illustrated in FIG. 13A, FIG. 13B, FIG. 13C, and FIG. 13D is an application example of the form of FIG. 7A and FIG. 7B. FIG. 13B is a sectional view at a position taken along the line A-A′ illustrated in FIG. 13A. Further, FIG. 13C is a sectional view at a position taken along the line B-B′ illustrated in FIG. 13A. Further, FIG. 13D is a sectional view at a position taken along the line C-C′ illustrated in FIG. 13A. Also in the photoelectric conversion device of the present embodiment, the P-type semiconductor region PDS can be provided under the bottoms of the N-type semiconductor regions 44a and 44b. It is therefore possible to increase the saturation charge amount of the photoelectric conversion units PD1 and PD2.

### Sixth Embodiment

A photoelectric conversion device of the present embodiment will be described mainly for features different from the first embodiment.

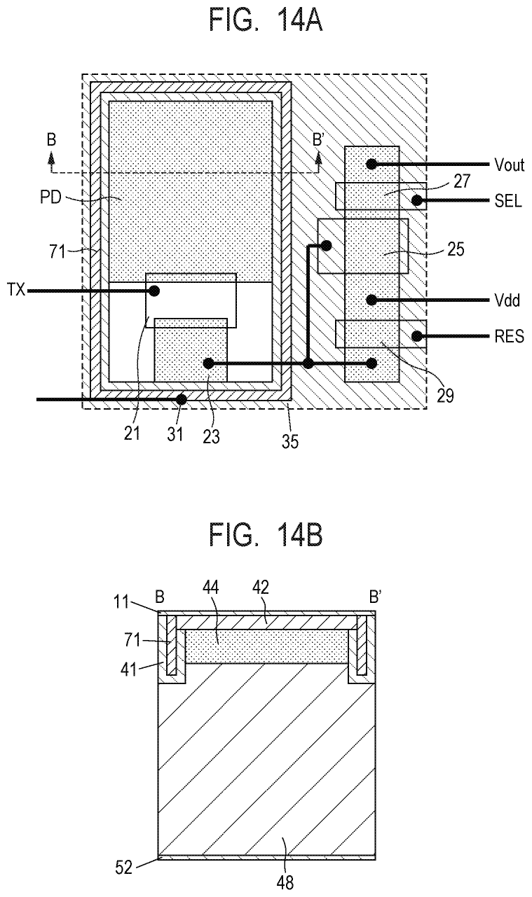

FIG. 14A and FIG. 14B are top views of a pixel of a photoelectric conversion device of the present embodiment. In FIG. 14A and FIG. 14B, members having the same function as those illustrated in FIG. 3 are also labeled with the same references as those in FIG. 3.

The photoelectric conversion device of the present embodiment is provided with an insulating member 71 inside the P-type isolation region 41. As the insulating member 71, silicon oxide, silicon nitride, silicon oxynitride, or the like can be used.

The front electrode 31 is connected to the P-type isolation region 41.

The insulating member 71 is covered with the P-type isolation region 41. It is therefore possible to suppress a dark current occurring due to the provided insulating member 71 from flowing into the N-type semiconductor region 44.

By providing the insulating member 71, the width of a region used for isolating pixels from each other can be smaller than that of the first embodiment. This enables an increase in the number of the pixels in a pixel array and a reduction in the size of a pixel array.

### Seventh Embodiment

A photoelectric conversion device of the present embodiment will be described mainly for features different from the first embodiment.

In the present embodiment, a front electrode (well contact 81) is shared by a plurality of pixels.

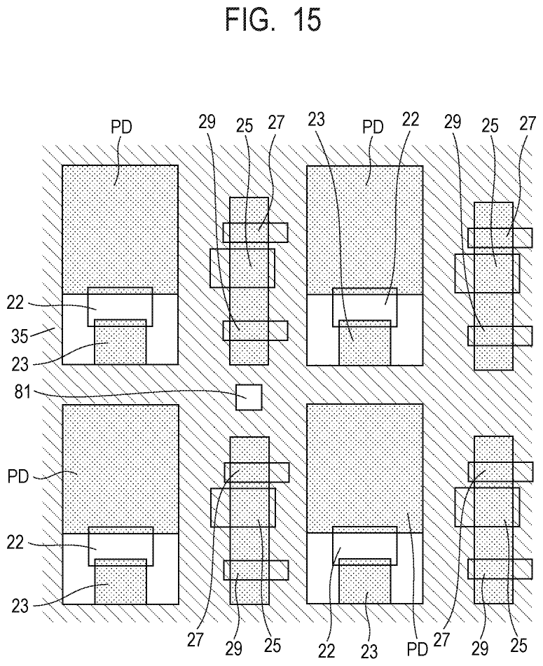

FIG. 15 is a top view of a photoelectric conversion device of the present embodiment. In FIG. 15, members having the same function as those illustrated in FIG. 3 are also labeled with the same references as those in FIG. 3.

A single well contact 81 electrically connecting the front electrode to the P-type isolation region 41 is provided to pixels of a plurality of rows and a plurality of columns. In the example of FIG. 15, the single well contact 81 is provided to four pixels of two rows and two columns.

To reduce electrical resistance between the back electrode 52 and the front electrode 31, it is preferable to provide the well contact 81 for each pixel. However, since the increased number of the well contact 81 requires an increase in the pixel pitch accordingly, this prevents an increase in number of pixels and a reduction in the size of the pixel array. Alternatively, since it is necessary to reduce the area of the photoelectric conversion unit PD in order to suppress an increase in the pixel pitch, this causes a reduction in sensitivity.

To further increase the number of the pixels and reduce the size of the pixel array, it is preferable that the well contact 81 be shared by a plurality of pixels as far as the reduction in the electrical resistance between the back electrode 52 and the front electrode 31 can be tolerated.

Therefore, the photoelectric conversion device of the present embodiment has an advantage of facilitating a further increase in the number of the pixels and a further reduction in the size of the pixel array by sharing the well contact 81 by a plurality of pixels. Further, since a reduction of the area of the photoelectric conversion unit PD can be suppressed, the likelihood of occurrence of a reduction in sensitivity can be reduced.

### Eighth Embodiment

A photoelectric conversion device of the present embodiment will be described mainly for features different from the first embodiment.

The layout of the photoelectric conversion device of the present embodiment when viewed from the top face may be the same as that of FIG. 3.

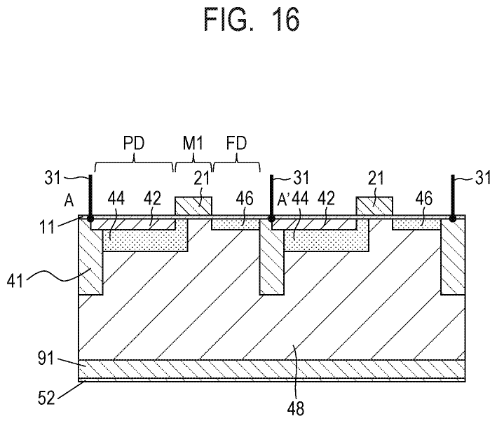

FIG. 16 is a sectional view at a position taken along the line A-A′ illustrated in FIG. 3. In FIG. 16, members having the same function as those illustrated in FIG. 4A and FIG. 4B are also labeled with the same references as those in FIG. 4A and FIG. 4B.

In the present embodiment, a P-type semiconductor region 91 is provided on the back electrode 52. The P-type semiconductor region 91 has a higher impurity concentration than the P-type semiconductor region 48. Typically, the impurity concentration can be substantially the same as that of the P-type isolation region 41.

In the form of FIG. 3, an electron current due to electrons injected from the back electrode 52 also flows in accordance with the hall current flowing between the P-type isolation region 41 and the back electrode 52. When the electrons caused by the electron current enter the N-type semiconductor region 44, this causes noise. The noise is likely to be visually recognized when less light enters the photoelectric conversion unit PD (that is, in a case of low brightness).

In the present embodiment, the P-type semiconductor region 91 is provided on the back electrode 52. With such a configuration, electrons injected from the back electrode 52 are offset by holes of the P-type semiconductor region 91. Thereby, since the injection of unnecessary electrons into the N-type semiconductor region 44 is suppressed, noise can be reduced.

As described above, in the photoelectric conversion device of the present embodiment, by providing the P-type semiconductor region 91 on the back electrode 52, it is possible to prevent injection of unnecessary electrons from the back electrode 52 to the N-type semiconductor region 44. Accordingly, noise can be reduced.

### Ninth Embodiment

A photoelectric conversion device of the present embodiment will be described mainly for features different from the first embodiment. The present embodiment is a photoelectric conversion device that forms an electric potential gradient in the P-type semiconductor region 48 without using the back electrode.

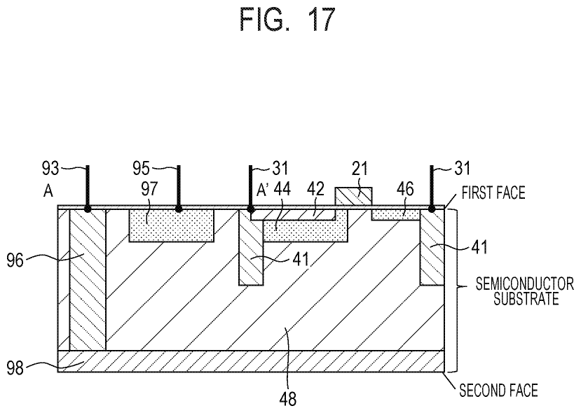

FIG. 17 is a sectional view at a position taken along the line A-A′ illustrated in FIG. 3. In FIG. 17, members having the same function as those illustrated in FIG. 4A and FIG. 4B are also labeled with the same references as those in FIG. 4A and FIG. 4B.

In the present embodiment, a P-type semiconductor region 98 is provided under the bottom of the P-type semiconductor region 48. The impurity concentration of the P-type semiconductor region 98 is higher than that of the P-type semiconductor region 48.

Typically, the P-type semiconductor region 98 is formed along the second face of the semiconductor substrate so as to be in contact with the second face.

In addition, a P-type isolation region 96 is provided so as to extend in the depth direction from the first face of the semiconductor substrate to the P-type semiconductor region 98. The P-type isolation region 96 and the P-type semiconductor region 98 can have substantially the same impurity concentration.

The P-type isolation region 96 is connected to the front electrode 93. A voltage applied by the front electrode 93 may be the same as the voltage applied by the back electrode of the first embodiment.

Note that, in such a form, an N-type semiconductor region 97 is provided as a guard ring in order to reduce a current flowing due to a voltage difference between the P-type isolation region 96 and the P-type isolation region 41. A predetermined electric potential is applied to the N-type semiconductor region 97 from the front electrode 95. Typically, the electric potential between the electric potential of the P-type isolation region 96 and the electric potential of the P-type isolation region 41 is applied to the N-type semiconductor region 97. Thereby, a current flowing between the P-type isolation region 96 and the P-type isolation region 41 can be reduced.

As described above, in the present embodiment, it is possible to form an electric potential gradient in the P-type semiconductor region 48 without providing the back electrode. Further, by providing a guard ring, it is possible to reduce a current flowing between the P-type isolation region 96 and the P-type isolation region 41.

### Tenth Embodiment

A photoelectric conversion device of the present embodiment will be described mainly for features different from the first embodiment.

The photoelectric conversion device of the present embodiment has a pixel used for receiving visible light and a pixel used for receiving near-infrared light and/or infrared light having a longer wavelength than visible light.

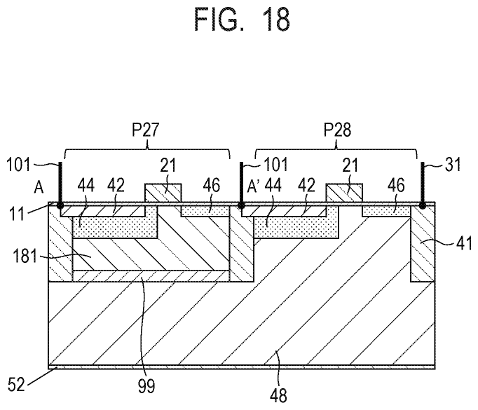

FIG. 18 is a diagram illustrating a cross section of the photoelectric conversion device of the present embodiment. In FIG. 18, members having the same function as those illustrated in FIG. 4A and FIG. 4B are also labeled with the same references as those in FIG. 4A and FIG. 4B.

A pixel P27 is a pixel used for receiving visible light. A pixel P28 is a pixel used for receiving a light having a longer wavelength than visible light.

In the pixel P27, a P-type semiconductor region 181 is provided under the bottom of the N-type semiconductor region 44. The impurity concentration of the P-type semiconductor region 181 can be substantially the same as that of the P-type semiconductor region 48.

To electrically isolate the P-type semiconductor region 181 and the P-type semiconductor region 48 from each other, a P-type isolation region 99 is provided for processing the P-type semiconductor region 181. A predetermined electric potential is provided to the P-type isolation region 99 from the front electrode 101.

The configuration of the pixel P28 may be the same as that of the first embodiment.

With the P-type isolation region 99 being provided, the pixel P27 can suppress electrons generated in the P-type semiconductor region 48 from flowing into the N-type semiconductor region 44 of the pixel P27.

Accordingly, it is possible to suppress signal charges based on a light having a longer wavelength than visible light from flowing into the pixel P27.

Accordingly, it is possible to improve accuracy of the signal of the pixel P27 that photoelectrically converts visible light and cause the color ratio of an image to be closer to the color ratio of a subject.

### Eleventh Embodiment

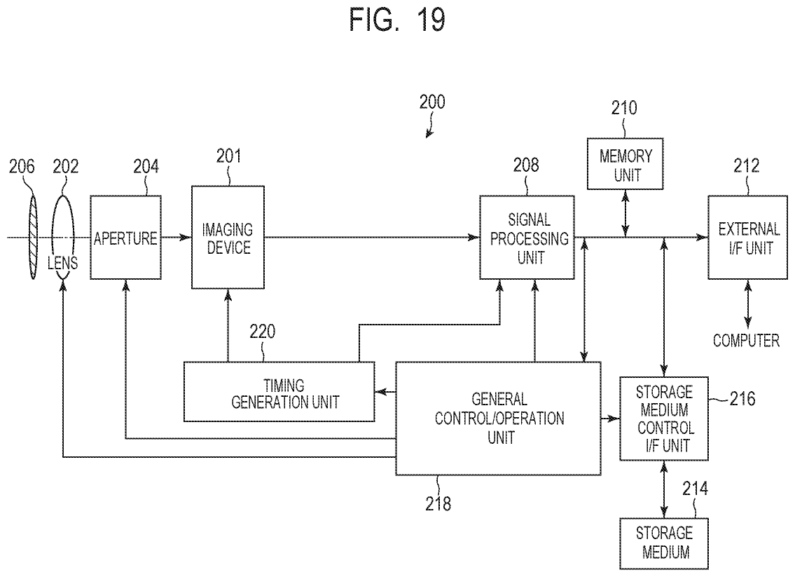

An imaging system according to the present embodiment will be described by using FIG. 19. Components similar to those of the photoelectric conversion devices of the embodiments described above are labeled with the same reference, and the description thereof will be omitted or simplified. FIG. 19 is a block diagram illustrating the general configuration of a photoelectric conversion system according to the present embodiment.

The photoelectric conversion device described in each embodiment described above can be applied to various imaging systems as an imaging device 201 of FIG. 19. An applicable example of the photoelectric conversion system may be a digital still camera, a digital camcorder, a surveillance camera, a copying machine, a fax machine, a mobile phone, an on-vehicle camera, an observation satellite, or the like. Further, the photoelectric conversion system includes a camera module having an optical system such as a lens and the imaging device. FIG. 19 illustrates a block diagram of a digital still camera as one example of these systems.

The imaging system will be described below as one example of the photoelectric conversion system. The imaging system 200 illustrated in FIG. 19 has the imaging device 201, a lens 202 that captures an optical image of a subject onto the imaging device 201, an aperture 204 used for changing the amount of light that has passed through the lens 202, and a barrier 206 used for protecting the lens 202. The lens 202 and the aperture 204 form an optical system that converges light onto the imaging device 201.

The imaging system 200 further has a signal processing unit 208 that processes output signals output by the imaging device 201. The signal processing unit 208 performs AD conversion that converts an analog signal output from the imaging device 201 into a digital signal. In addition, the signal processing unit 208 further performs an operation that performs various correction or compression to output image data, if necessary. An AD conversion unit that is a part of the signal processing unit 208 may be formed on the semiconductor substrate on which the imaging device 201 is provided or may be formed on a substrate separated from the imaging device 201. Further, the imaging device 201 and the signal processing unit 208 may be formed on the same semiconductor substrate.

The imaging system 200 further has a memory unit 210 used for temporarily storing image data and an external interface unit (external I/F unit) 212 used for communicating with an external computer or the like. The imaging system 200 further has a storage medium 214 such as a semiconductor memory used for performing storage or readout of imaging data and a storage medium control interface unit (storage medium control I/F unit) 216 used for performing storage or readout on the storage medium 214. Note that the storage medium 214 may be embedded in the imaging system 200 or may be removable.

Furthermore, the imaging system 200 has a general control/operation unit 218 that performs various operations and controls the entire digital still camera and a timing generation unit 220 that outputs various timing signals to the imaging device 201 and the signal processing unit 208. Here, a timing signal or the like may be input externally, and the imaging system 200 may have at least the imaging device 201 and the signal processing unit 208 that processes output signals output from the imaging device 201.

The imaging device 201 outputs an imaging signal to the signal processing unit 208. The signal processing unit 208 performs predetermined signal processing on an imaging signal output from the imaging device 201 and outputs image data. The signal processing unit 208 uses an imaging signal to generate an image.

By applying the photoelectric conversion device according to each embodiment described above as the imaging device 201, it is possible to realize an imaging system or a photoelectric conversion system that can stably acquire a good quality image having high sensitivity and a large amount of a saturation signal.

### Twelfth Embodiment

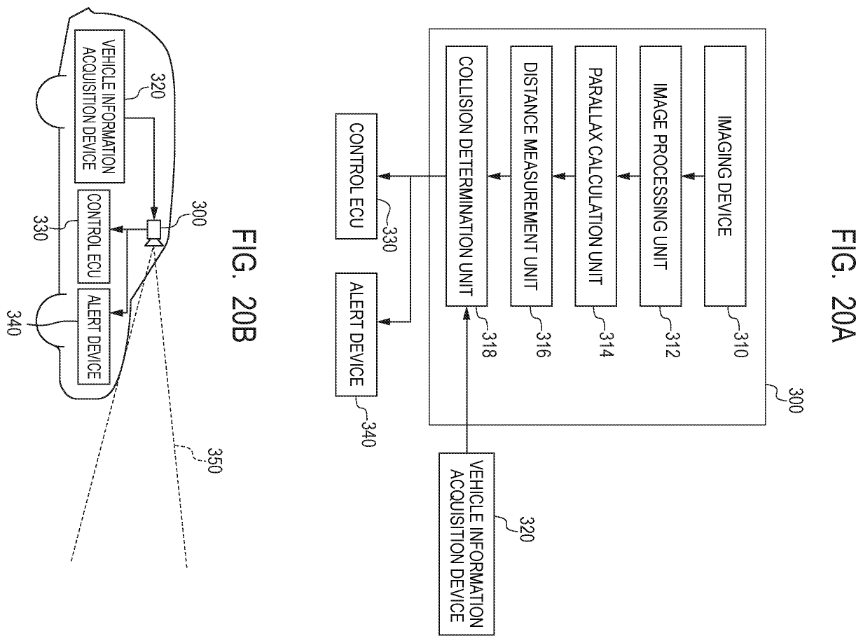

A photoelectric conversion system and a mobile apparatus according to the present embodiment will be described by using FIG. 20A and FIG. 20B. FIG. 20A and FIG. 20B are diagrams illustrating the configuration of an imaging system and the mobile apparatus according to the present embodiment.

FIG. 20A illustrates an example of an imaging system related to an on-vehicle camera. The imaging system 300 has an imaging device 310. The imaging device 310 is the photoelectric conversion device described in any of the embodiments described above. The imaging system 300 has an image processing unit 312 that performs image processing on a plurality of image data acquired by the imaging device 310 and a parallax calculation unit 314 that calculates a parallax (a phase difference of parallax images) from the plurality of image data acquired by the imaging system 300. Further, the imaging system 300 has a distance measurement unit 316 that calculates a distance to the object based on the calculated parallax and a collision determination unit 318 that determines whether or not there is a collision possibility based on the calculated distance. Here, the parallax calculation unit 314 and the distance measurement unit 316 are an example of a distance information acquisition unit that acquires distance information on the distance to the object. That is, the distance information is information on a parallax, a defocus amount, a distance to an object, or the like. The collision determination unit 318 may use any of the distance information to determine the collision possibility. The distance information acquisition unit may be implemented by dedicatedly designed hardware or may be implemented by a software module. Further, the distance information acquisition unit may be implemented by a Field Programmable Gate Array (FPGA), an Application Specific Integrated Circuit (ASIC), or the like or may be implemented by combination thereof.

The imaging system 300 is connected to the vehicle information acquisition device 320 and can acquire vehicle information such as a vehicle speed, a yaw rate, a steering angle, or the like. Further, the imaging system 300 is connected to a control ECU 330, which is a control device that outputs a control signal for causing a vehicle to generate braking force based on a determination result by the collision determination unit 318. Further, the imaging system 300 is also connected to an alert device 340 that issues an alert to the driver based on a determination result by the collision determination unit 318. For example, when the collision probability is high as the determination result of the collision determination unit 318, the control ECU 330 performs vehicle control to avoid a collision or reduce damage by applying a brake, pushing back an accelerator, suppressing engine power, or the like. The alert device 340 alerts a user by sounding an alert such as a sound, displaying alert information on a display of a car navigation system or the like, providing vibration to a seat belt or a steering wheel, or the like.

In the present embodiment, an area around a vehicle, for example, a front area or a rear area is captured by using the imaging system 300. FIG. 20B illustrates the imaging system when a front area of a vehicle (a capturing area 350) is captured. The vehicle information acquisition device 320 transmits an instruction to the imaging system 300 or the imaging device 310 so as to perform a predetermined operation. Such a configuration can further improve the ranging accuracy.

Although the example of control for avoiding a collision to another vehicle has been described above, the embodiment is also applicable to automatic driving control for following another vehicle, automatic driving control for not going out of a traffic lane, or the like. Furthermore, the imaging system is not limited to a vehicle such as the subject vehicle and can be applied to a mobile apparatus (moving apparatus) such as a ship, an airplane, or an industrial robot, for example. In addition, the imaging system can be widely applied to a device which utilizes object recognition, such as an intelligent transportation system (ITS), without being limited to mobile apparatuses.

### Modified Embodiments

The disclosure is not limited to the embodiments described above, and various modifications are possible.

For example, an example in which a part of the configuration of any of the embodiments is added to another embodiment or an example in which a part of the configuration of any of the embodiments is replaced with a part of the configuration of another embodiment is one of the embodiments.

Further, while the solid state imaging device using a photoelectric conversion unit PD that generates electrons as signal charges has been illustrated as an example in the embodiments described above, a solid state imaging device using a photoelectric conversion unit PD that generates holes as signal charges can also be applicable in the same manner. In such a case, the conductivity type of the semiconductor region forming each portion of a pixel is the opposite conductivity type.

Embodiments of the disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiments and/or that includes one or more circuits (e.g., application specific integrated circuit (ASIC)) for performing the functions of one or more of the above-described embodiments, and by a method performed by the computer of the system or apparatus by, for example, reading out and executing the computer executable instructions from the storage medium to perform the functions of one or more of the above-described embodiments and/or controlling the one or more circuits to perform the functions of one or more of the above-described embodiments. The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2018-224279, filed Nov. 29, 2018 which is hereby incorporated by reference herein in its entirety.

What is claimed is:

1. A photoelectric conversion device comprising a semiconductor substrate having a first face and a second face,
wherein the semiconductor substrate includes
at least one first semiconductor region of a first conductivity type provided at a position at which a depth from the first face is a first depth,
a second semiconductor region of a second conductivity type provided at a second depth deeper than the first depth from the first face, being in contact with the first semiconductor region, and applied with a first electric potential from the second face side, and
a third semiconductor region of the second conductivity type extending from the first depth to a third depth shallower than the second depth, and being in contact with the first semiconductor region and the second semiconductor region, wherein the third semiconductor region has a higher impurity concentration than the second semiconductor region, and the third semiconductor region is applied with a second electric potential, the second electric potential being an electric potential lower than the first electric potential for an electric charge serving as a carrier of a semiconductor region of the first conductivity type.

2. The photoelectric conversion device according to claim 1,
wherein the semiconductor substrate further includes a fourth semiconductor region of the second conductivity type on the first face side of the first semiconductor region, and
wherein the third semiconductor region is in contact with the fourth semiconductor region.

3. The photoelectric conversion device according to claim 1,
wherein the semiconductor substrate includes a fifth semiconductor region of the second conductivity type under a bottom of the first semiconductor region, and
wherein the fifth semiconductor region has a higher impurity concentration than the second semiconductor region.

4. The photoelectric conversion device according to claim 3, wherein the fifth semiconductor region is in contact with the third semiconductor region.

5. The photoelectric conversion device according to claim 1,
wherein the semiconductor substrate includes
a sixth semiconductor region of the second conductivity type extending along the second face, provided at a position at which a depth from the first face is deeper than the second depth, and having a higher impurity concentration than the second semiconductor region, and
a seventh semiconductor region of the second conductivity type extending in the depth direction from the first face so as to be in contact with the sixth semiconductor region, and
wherein by an electric potential being applied to the seventh semiconductor region, the first electric potential is applied to the second semiconductor region via the sixth semiconductor region.

6. The photoelectric conversion device according to claim 1 further comprising an electrode that applies the first electric potential to the second semiconductor region,
wherein the electrode is provided extending along the second face.

7. The photoelectric conversion device according to claim 6, wherein the semiconductor substrate includes an eighth semiconductor region of the second conductivity type having a higher impurity concentration than the second semiconductor region between the electrode and the second semiconductor region.

8. The photoelectric conversion device according to claim 6,
wherein the photoelectric conversion device is configured such that a light enters the first semiconductor region from the first face, and
wherein the electrode is a metal that reflects a light that has transmitted through the first semiconductor region and the second semiconductor region.

9. The photoelectric conversion device according to claim 6,
wherein the photoelectric conversion device is configured such that a light enters the first semiconductor region from the second face, and
wherein the electrode is a transparent electrode.

10. The photoelectric conversion device according to claim 9 further comprising an antireflection film, the electrode being provided between the antireflection film and the second face.

11. The photoelectric conversion device according to claim 1 further comprising one or more micro-lenses,
wherein a plurality of first semiconductor regions are provided, and
wherein the plurality of first semiconductor regions are provided in association with one micro-lens of the one or more micro-lenses.

12. The photoelectric conversion device according to claim 11, wherein the semiconductor substrate further includes a ninth semiconductor region of the second conductivity type between the plurality of first semiconductor regions.

13. The photoelectric conversion device according to claim 12, wherein the ninth semiconductor region is provided ranging from a depth at which the first semiconductor region is provided to the third depth.

14. The photoelectric conversion device according to claim 1, wherein the semiconductor substrate further includes an insulating member provided inside the third semiconductor region.

15. The photoelectric conversion device according to claim 1 further comprising a plurality of pixels each including the first semiconductor region and the third semiconductor region,
wherein the third semiconductor region of one of the plurality of pixels is in contact with the third semiconductor region of another of the plurality of pixels, and
wherein the photoelectric conversion device further comprises a contact used for applying the second electric potential to the third semiconductor region of each of the plurality of pixels, and the contact is shared by the plurality of pixels.

16. The photoelectric conversion device according to claim 1 further comprising a first pixel which a visible light enters and a second pixel which a light having a longer wavelength than the visible light enters,
wherein each of the first pixel and the second pixel includes the first semiconductor region,
wherein a tenth semiconductor region of the second conductivity type, an eleventh semiconductor region of the second conductivity type, and the third semiconductor region are provided in ascending order of depth with respect to the first semiconductor region of the first pixel when viewed from the first face, and
wherein the eleventh semiconductor region has a higher impurity concentration than each of the tenth semiconductor region and the third semiconductor region.

17. The photoelectric conversion device according to claim 16, wherein the tenth semiconductor region is surrounded by the eleventh semiconductor region.

18. A photoelectric conversion system comprising:
the photoelectric conversion device according to claim 1; and
a signal processing unit configured to process signals output from the photoelectric conversion device.

19. A mobile apparatus comprising:
the photoelectric conversion device according to claim 1;
a distance information acquisition unit configured to acquire distance information on a distance to an object, from a parallax image based on signals output from the photoelectric conversion device; and
a control unit configured to control the mobile apparatus based on the distance information.
